(19) United States
(12) Patent Application Publication
(10) Pub. No.: US 2025/0349629 A1
(43) Pub. Date: Nov. 13, 2025

(54) PACKAGE STRUCTURE AND METHOD FOR FORMING THE SAME

(71) Applicant: TAIWAN SEMICONDUCTOR MANUFACTURING COMPANY, LTD., Hsinchu (TW)

(72) Inventors: Chih-Chien PAN, Taipei City (TW); Chun-Yen LAN, Hsinchu County (TW); Pu WANG, Hsinchu City (TW); Li-Hui CHENG, New Taipei City (TW); Ying-Ching SHIH, Hsinchu City (TW)

(73) Assignee: TAIWAN SEMICONDUCTOR MANUFACTURING COMPANY, LTD., Hsinchu (TW)

(21) Appl. No.: 18/659,311

(22) Filed: May 9, 2024

(51) Int. Cl. H01L 23/04; H01L 21/56; H01L 23/00; H01L 23/31; H01L 23/367; H01L 25/16

(52) U.S. Cl. CPC H01L 23/04; H01L 21/56; H01L 23/3121; H01L 23/367; H01L 24/16; H01L 25/16; H01L 2224/16225; H01L 2924/1815

(57) ABSTRACT

A package structure includes a substrate. A package is over the substrate. A contour ring is mounted over the substrate, in which the contour ring surrounds the package and has an opening. A top lid is mounted over the contour ring, in which the top lid has a portion extending into the opening of the contour ring.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

As the demand for shrinking electronic devices has grown, a need for smaller and more creative packaging techniques of semiconductor dies has emerged. An example of such packaging systems is Package-on-Package (POP) technology. In a PoP device, a top semiconductor package is stacked on top of a bottom semiconductor package to provide a high level of integration and component density. Another example is a Chip-On-Wafer-On-Substrate (CoWoS) structure, where a semiconductor chip is attached to a wafer (e.g., an interposer) to form a Chip-On-Wafer (CoW) structure. The CoW structure is then attached to a substrate (e.g., a printed circuit board) to form a CoWoS structure. These and other advanced packaging technologies enable production of semiconductor devices with enhanced functionalities and small footprints.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A to 5B illustrate a method in various stages of forming a package structure in accordance with some embodiments of the present disclosure.

FIG. 6 is a cross-sectional view of a package structure in accordance with some embodiments of the present disclosure.

FIGS. 7A to 9B illustrate a method in various stages of forming a package structure in accordance with some embodiments of the present disclosure.

FIG. 10 is a cross-sectional view of a package structure in accordance with some embodiments of the present disclosure.

FIGS. 11A to 14B illustrate a method in various stages of forming a package structure in accordance with some embodiments of the present disclosure.

FIG. 15 is a cross-sectional view of a package structure in accordance with some embodiments of the present disclosure.

FIGS. 16A and 16B are cross-sectional views of a package structure in accordance with some embodiments of the present disclosure.

FIG. 17 is a cross-sectional view of a package structure in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

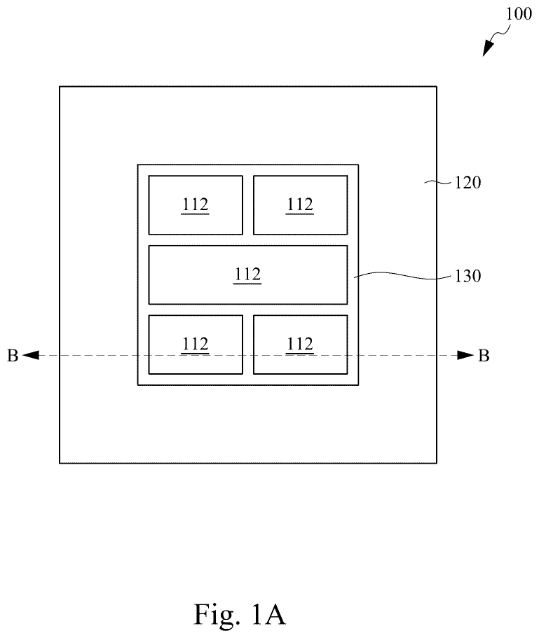

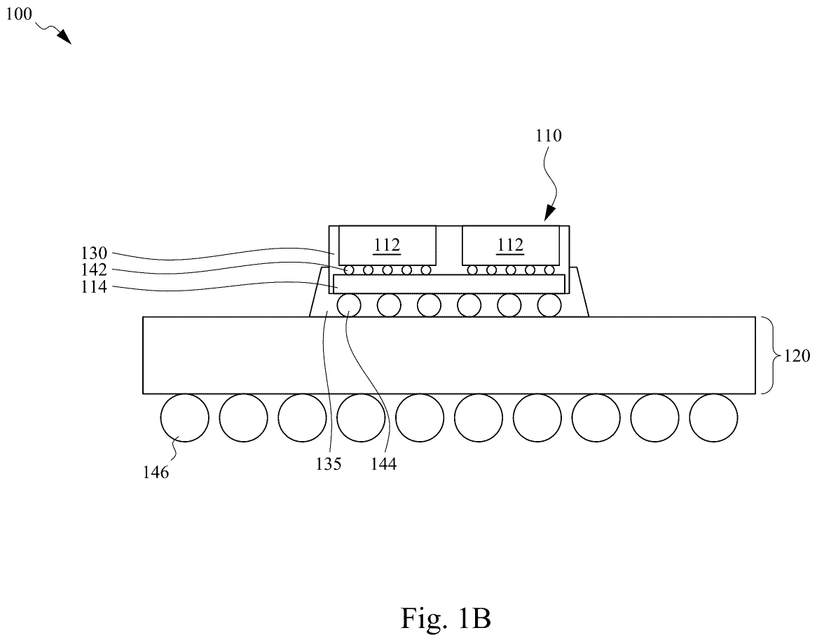

FIGS. 1A to 5B illustrate a method in various stages of forming a package structure in accordance with some embodiments of the present disclosure. FIGS. 1A, 2A, 3A, 4A, and 5A are top views of a package structure, and FIGS. 1B, 2B, 3B, 4B, and 5B are cross-sectional views of a package structure. In greater detail, FIGS. 1B, 2B, 3B, 4B, and 5B are cross-sectional views along line B-B of FIGS. 1A, 2A, 3A, 4A, and 5A, respectively.

Reference is made to FIGS. 1A and 1B. Shown there is a package structure 100. In some embodiments, the package structure 100 may be a three-dimensional integrated circuit (3DIC) package. In some embodiments, the 3DIC package may include a Chip-on-Wafer-on-Substrate (CoWoS) package structure. In other embodiments, the package structure 100 may include chip stacking such as logic-on-logic (LOL), memory-on-logic (MoL), or the like.

The package structure 100 includes a package 110 and a substrate 120 bonded with each other. In greater detail, the package 110 is disposed on a top surface of the substrate 120. In some embodiments, the package 110 may be a Chip-on-Wafer (CoW) package.

The package 110 may include a plurality of dies 112. The dies 112 may also be referred to as chips. As shown in the top view of FIG. 1A, five dies 112 are illustrated, while the present disclosure is not limited thereto. In other embodiments, more or less dies 112 may also be employed. In some embodiments, the dies 112 may include high-power consuming die and/or ow-power consuming dies. For example, the high-power consuming die may consume a relatively high amount of power and, therefore, generates a relatively large amount of heat compared to the lower-power consuming dies. The high-power consuming die may be a processor, such as a central processing unit (CPU), a graphics processing unit (GPU), or the like. The low-power consuming dies may be memory dies such as high bandwidth memory (HBM), memory cubes, memory stacks, or the like.

The dies 112 are bonded to a top surface of a package component 114. The dies 112 may be electrically and mechanically coupled to the package component 114 through a plurality of first connectors 142. In some embodiments, the first connectors 142 may be conductive bumps, micro bumps, metal pillars, or the like.

The dies 112 may be surrounded by an encapsulant 130 which includes a molding compound. The dies 112 and the encapsulant 130 may be planarized such that top surfaces of the dies 112 and the encapsulant 130 are substantially level with each other. In some embodiments, the encapsulant 130 may also surround the first connectors 142. In some embodiments, the encapsulant 130 may also extends to sidewalls of the package component 114. In other embodiments, the encapsulant 130 may surround the dies 112, while the first connectors 142 and the package component 114 may be free of coverage by the encapsulant 130.

The package component 114 may be an interposer substrate, which may be a semiconductor substrate. For example, the package component 114 may be a silicon substrate. The package component 114 may also be formed of another semiconductor material such as silicon germanium, silicon carbon, or the like. In accordance with some embodiments, active devices such as transistors (not separately illustrated) are formed at a surface of the package component 114. Passive devices (not separately illustrated) such as resistors and/or capacitors may also be formed in the package component 114. In accordance with alternative embodiments of the present disclosure, the package component 114 may be a semiconductor substrate or a dielectric substrate, and the respective package component 114 may not include active devices therein. In accordance with these embodiments, the package component 114 may, or may not, include passive devices formed therein.

Although not shown in the cross-sectional view of FIG. 1B, through vias may be formed to extend from the top surface of the package component 114 into the package component 114. The through vias may be referred to as through-substrate vias or through-silicon vias in embodiments where the package component 114 is a silicon substrate. In some embodiments, the package component 114 may include an interconnect structure which is used to electrically connect the integrated circuit devices in the package 110. The interconnect structure may include a plurality of dielectric layers, metal lines formed in the dielectric layers, and vias formed between, and interconnecting, the overlying and underlying metal lines. In accordance with some embodiments, the dielectric layers may be formed of silicon oxide, silicon nitride, silicon carbide, silicon oxynitride, combinations thereof, and/or multi-layers thereof. Alternatively, the dielectric layers may include one or more low-k dielectric layers having low dielectric constants (k values). The k values of the low-k dielectric materials in the dielectric layers may be lower than about 3.0 or lower than about 2.5, for example.

The package component 114 of the package 110 is bonded to the top surface of the substrate 120. The package component 114 may be electrically and mechanically coupled to the substrate 120 through a plurality of second connectors 144. In some embodiments, the second connectors 144 may be conductive bumps, micro bumps, metal pillars, or the like. An underfill material 135 may be formed between the package component 114 and the substrate 120, surrounding the second connectors 144. In the embodiments where the first connectors 142 are free of coverage by the encapsulant 130, the underfill material 135 may also extend between the dies 112 and the package component 114, surrounding the first connectors 142.

The substrate 120 may be a package substrate, which may be a printed circuit board (PCB) or the like. The substrate 120 may include one or more dielectric layers and electrically conductive features, such as conductive lines and vias. In some embodiments, the substrate 120 may include through-vias, active devices, passive devices, and the like. The substrate 120 may further include conductive pads formed at the upper and lower surfaces of the substrate 120. The second connectors 144 may be coupled to conductive pads at the top surface of the substrate 120. A plurality of third connectors 118 may be coupled to the conductive pads at the bottom surface of the substrate 120. In some embodiments, the third connectors 118 may be conductive bumps, micro bumps, metal pillars, or the like.

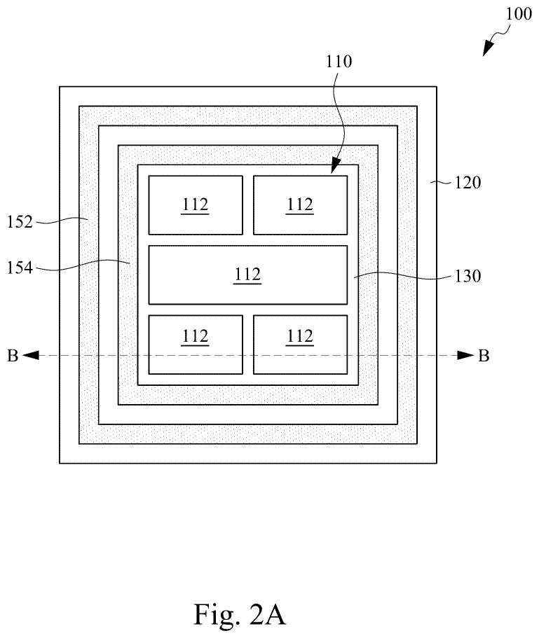

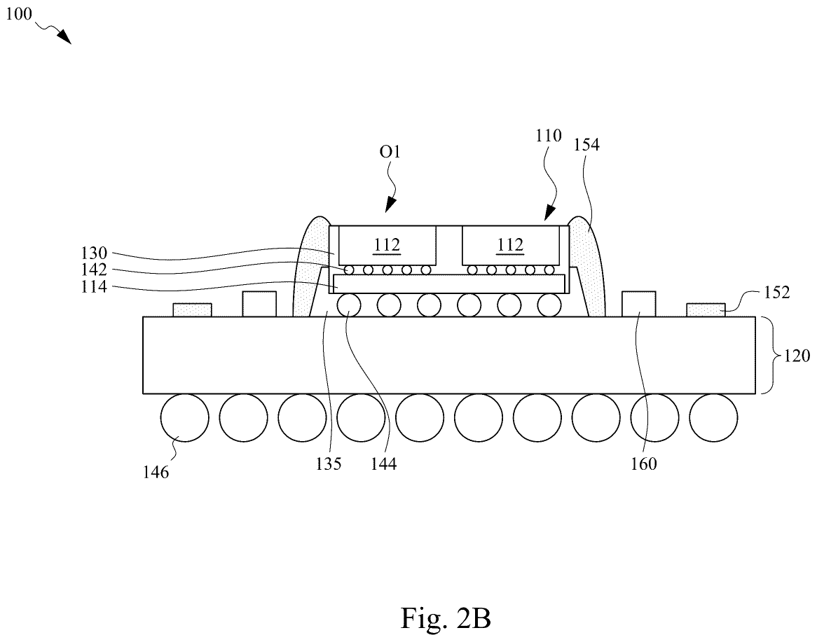

Reference is made to FIGS. 2A and 2B. Adhesive materials 152 and 154 are dispensed over the substrate 120. In some embodiments, the adhesive materials 152 and 154 may be an epoxy-based material (e.g., epoxy), a silicone-based material (e.g., silicon resin), a glue, or the like. In the top view of FIG. 2A, both of the adhesive materials 152 and 154 have a rectangular ring shape top profile. In greater detail, the adhesive material 152 surrounds the adhesive material 154. Moreover, the adhesive material 154 may surround the dies 112, and may also surround the encapsulant 130.

In the cross-sectional view of FIG. 2B, the adhesive material 152 is in contact with the top surface of the substrate 120. On the other hand, the adhesive material 154 may extends from the top surface of the encapsulant 130, passing through the sidewall of the encapsulant 130 and the sidewall of the underfill material 135, to the top surface of the substrate 120. That is, the adhesive material 154 may be in contact with the top surface of the encapsulant 130, the sidewall of the encapsulant 130, the sidewall of the underfill material 135, and the top surface of the substrate 120. Accordingly, the top surface of the adhesive material 154 may be higher than the top surface of the adhesive material 152, while the bottom surface of the adhesive material 154 may be substantially level with the bottom surface of the adhesive material 152.

In the cross-sectional view of FIG. 2B, one or more surface devices 160 may be disposed over the substrate 120. It is noted that the surface devices 160 are not illustrated in FIG. 2A for brevity. The surface devices 160 may be used to provide additional functionality or programming to the package 110, or the package structure 100. In some embodiments, the surface devices 160 may include surface mount devices (SMDs) or integrated passive devices (IPDs) that include passive devices such as resistors, inductors, capacitors, antennas, jumpers, combinations of these, or the like that are desired to be connected to and utilized in conjunction with the package 110, or other parts of the package structure 100. The surface devices 160 may be placed on the top surface of the substrate 120. In other embodiments, one or more surface devices 160 may also be disposed on the bottom surface of the substrate 120.

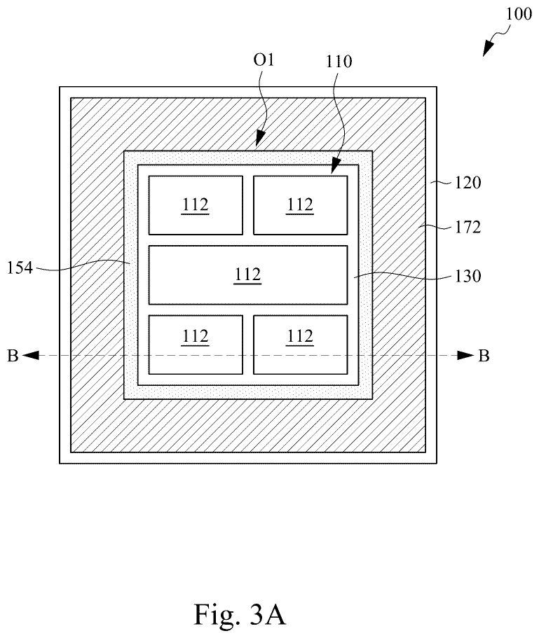

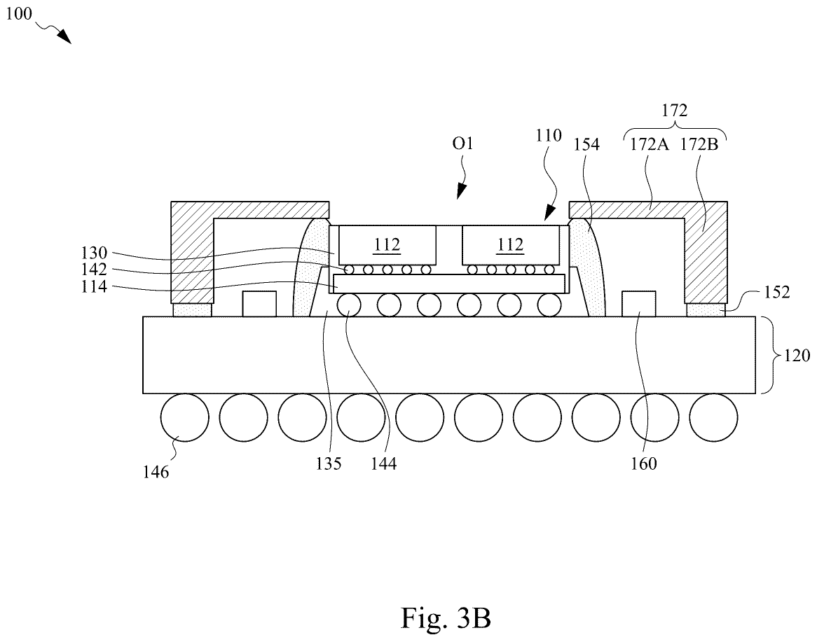

Reference is made to FIGS. 3A and 3B. A contour ring 172 is mounted over the substrate 120 and surrounding the package 110. As shown in the top view of FIG. 3A, the contour ring 172 has a rectangular ring shape top profile, which includes an opening O1. On the other hand, as shown in the cross-sectional view of FIG. 3B, the contour ring 172 is connected to the substrate 120 through the adhesive materials 152 and 154. In some embodiments, the contour ring 172 may include an L-shape cross-sectional view. For example, the contour ring 172 may include a horizontal portion 172A and a vertical portion 172B extends downward from one end of the horizontal portion 172A. The horizontal portion 172A of the contour ring 172 is in contact with the adhesive material 154, and the vertical portion 172B of the contour ring 172 is in contact with the adhesive material 152. In some embodiments, the bottom surface of the horizontal portion 172A of the contour ring 172 is higher than the top surfaces of the dies 112 and the encapsulant 130. The bottom surface of the horizontal portion 172A of the contour ring 172 may also be higher than the top surface of the top surface of the adhesive material 154.

As mentioned above, the contour ring 172 includes an opening O1. In some embodiments, the opening O1 may expose all of the dies 112 of the package 110. That is, in the cross-sectional view of FIG. 3B, the contour ring 172 may not overlap with the dies 112 along the vertical direction. In some embodiments, the contour ring 172 may not overlap with the encapsulant 130 that surrounds the dies 112. In the top view of FIG. 3A, the adhesive material 154 may be exposed, at least in part, through the opening O1 of the contour ring 172.

In some embodiments, the contour ring 172 may be a metal, a metal alloy, or the like. For example, the contour ring 172 may include metals and/or metal alloys such as Al, Cu, Ni, Co, combinations thereof, and the like. The contour ring 172 may also be formed of a composite material, for example silicon carbide, aluminum nitride, graphite, or the like. In some embodiments, the contour ring 172 may be a metal coated with another metal, such as gold. In some embodiments, the contour ring 172 may be a stainless material. The contour ring 172 may be formed of a material having a thermal conductivity from about 100 W/m. K to about 400 W/m. K, such as about 400 W/m. K. In some embodiments, the contour ring 172 is a single continuous material. That is, the horizontal portion 172A of the contour ring 172 may be in direct contact with the vertical portion 172B of the contour ring 172, which may increase the robustness of the contour ring 172. In other embodiments, the contour ring 172 may include multiple pieces that may be the same or different materials. For example, the horizontal portion 172A of the contour ring 172 and the vertical portion 172B of the contour ring 172 may be separated portions and may be connected with each other through an adhesive material.

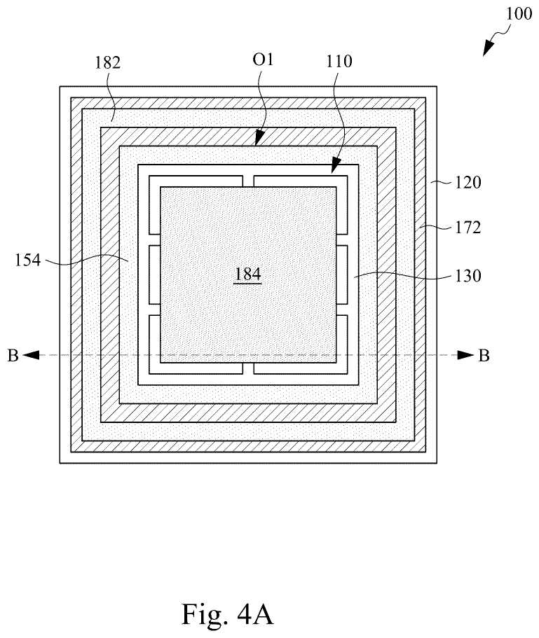

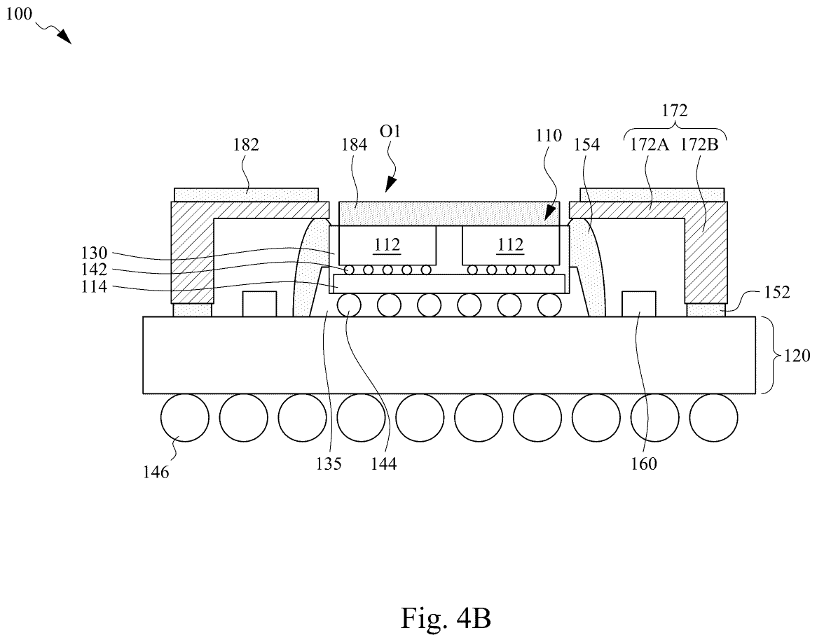

Reference is made to FIGS. 4A and 4B. An adhesive material 182 and a thermal interface material (TIM) 184 are dispensed over the contour ring 172 and the package 110, respectively. In greater detail, the adhesive material 182 is dispensed over and in contact with the horizontal portion 172A of the contour ring 172. The thermal interface material 184 is dispensed over and in contact with top surfaces of the dies 112 and the encapsulant 130. In some embodiments, the bottom surface of the thermal interface material 184 may be lower than the bottom surface of the adhesive material 182. The thermal interface material 184 may be spaced apart from the contour ring 172 and the adhesive material 182.

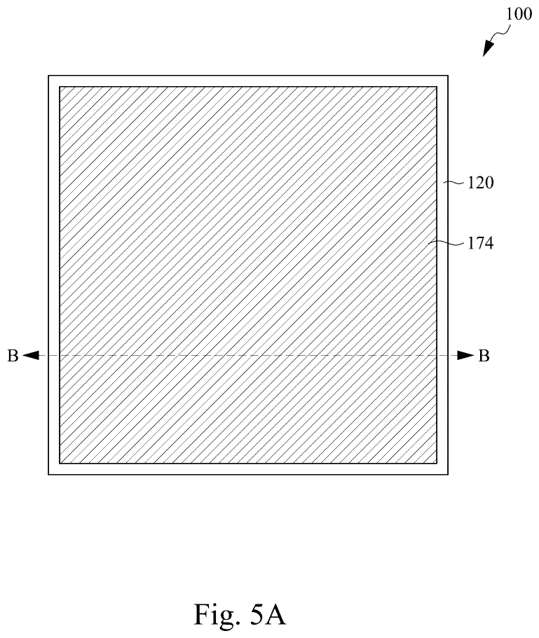

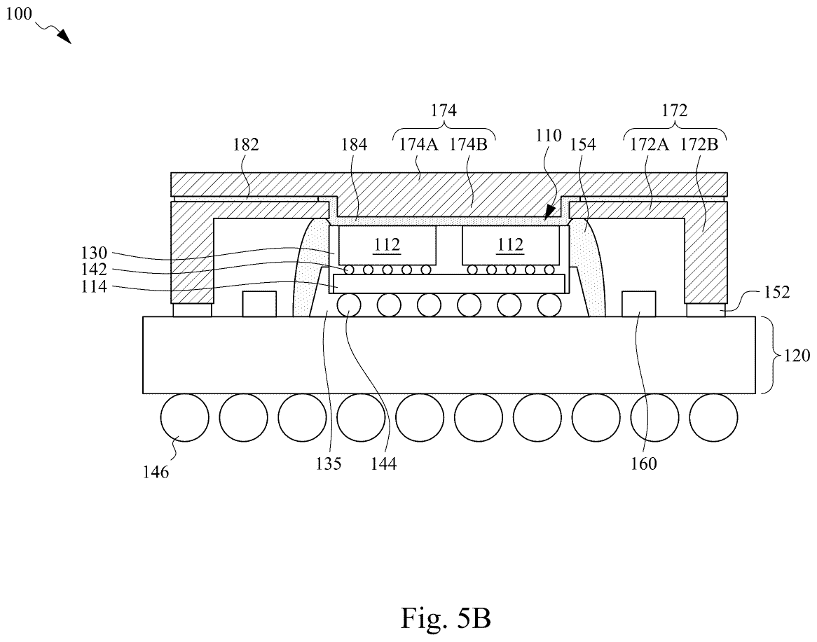

The adhesive material 182 may be an epoxy, a silicon resin, a glue, or the like. The adhesive material 182 may include a greater adhering ability than the thermal interface material 184, while the thermal interface material 184 may include a greater thermal conductivity than the adhesive material 182. The adhesive material 182 may have a thermal conductivity from about 1 W/m. K to about 3 W/m. K, lower than about 0.5 W/m. K, or the like. The adhesive material 182 may be positioned so as to allow the following formed top lid (e.g., top lid 174 in FIGS. 5A and 5B) to be attached over the contour ring 172. Thus, in some embodiments, the adhesive material 182 may be disposed along the top surface of the contour ring 172, and may also include a rectangular ring shape top profile. In some embodiments, the adhesive materials 152, 154, and 182 may be made of a same material that is different from the material of the thermal interface material 184.

The thermal interface material 184 may be a polymer having a good thermal conductivity, which may be from about 3 W/m. K to about 5 W/m·K. In some embodiments, the thermal interface material 184 may include a polymer with thermal conductive fillers. The thermal conductive fillers may increase the effective thermal conductivity of the thermal interface material 184 to be from about 10 W/m. K to about 50 W/m. K or more. Applicable thermal conductive filler materials may include aluminum oxide, boron nitride, aluminum nitride, aluminum, copper, silver, indium, a combination thereof, or the like. In other embodiments, the thermal interface material 184 may comprise other materials such as a metallic-based or solder-based material comprising silver, indium paste, or the like. In still further embodiments, the thermal interface material 184 may comprise a film-based or sheet-based material, such as a sheet-based material including synthesized carbon nanotubes (CNTs) or a thermally conductive sheet having vertically oriented graphite fillers. Although the thermal interface material 184 is illustrated as a continuous material extending over the dies 112, in other embodiments, the thermal interface material 184 may include several separated portions. In some embodiments, the thermal interface material 184 may be dispensed after the adhesive material 182; however, the thermal interface material 184 may also be dispensed before the adhesive material 182.

Reference is made to FIGS. 5A and 5B. A top lid 174 is mounted over the contour ring 172 and the package 110. In the cross-sectional view of FIG. 5B, the top lid 174 includes an upper portion 174A and a lower portion 174B extends downward from the upper portion 174A, in which the lower portion 174B is narrower than the upper portion 174A. The lower portion 174B of the top lid 174 extends into the opening O1 of the contour ring 172, such that the lower portion 174B of the top lid 174 may be laterally aligned, at least in part, with the horizontal portion 172A of the contour ring 172. The upper portion 174A of the top lid 174 may cover the package 110 and the contour ring 172. That is, the upper portion 174A of the top lid 174 may overlap with the contour ring 172 along the vertical direction. In greater detail, the upper portion 174A of the top lid 174 may overlap with the vertical portion 172B of the contour ring 172. In some embodiments, the bottom surface of the lower portion 174B of the top lid 174 may be higher than the dies 112.

During mounting the top lid 174 over the contour ring 172 and the package 110, the top lid 174 is placed over the contour ring 172 where the lower portion 174B of the top lid 174 extends into the opening O1 of the contour ring 172, such that the upper portion 174A of the top lid 174 is in contact with the adhesive material 182 and the lower portion of the top lid 174 is in contact with the thermal interface material 184. Then, the top lid 174 is pressed against the adhesive material 182 and the thermal interface material 184 to bond the top lid 174 with the contour ring 172 and the package 110. In some embodiments, the thermal interface material 184 may be pressed such that the thermal interface material 184 may laterally extend and may fill the space formed within the top lid 174, the contour ring 172, and the package 110. As a result, after the top lid 174 is mounted, the thermal interface material 184 may be in contact with sidewalls of the horizontal portion 172A of the contour ring 172. In some embodiments, the thermal interface material 184 may also extend to the top surface of the horizontal portion 172A of the contour ring 172 and in contact with the adhesive material 182. On the other hand, the thermal interface material 184 may be in contact with the bottom surface and sidewalls of the lower portion 174B of the top lid 174 and the bottom surface of the upper portion 174A of the top lid 174. In some embodiments, the thermal interface material 184 may also be in contact with the adhesive material 154 and the bottom surface of the horizontal portion 172A of the contour ring 172. This may improve the adhesion between the top lid 174 and the underlying structure and improve the thermal dissipation of the package structure 100.

In some embodiments, the top lid 174 may be a metal, a metal alloy, or the like. For example, the top lid 174 may include metals and/or metal alloys such as Al, Cu, Ni, Co, combinations thereof, and the like. The top lid 174 may also be formed of a composite material, for example silicon carbide, aluminum nitride, graphite, or the like. In some embodiments, the top lid 174 may be a metal coated with another metal, such as gold. In some embodiments, the top lid 174 may be a stainless material. The top lid 174 may be formed of a material having a thermal conductivity from about 100 W/m. K to about 400 W/m. K, such as about 400 W/m. K. In some embodiments, the top lid 174 is a single continuous material. That is, the upper portion 174A of the top lid 174 may be in direct contact with the lower portion 174B of the top lid 174, which may increase the robustness of the top lid 174. In some embodiments, the contour ring 172 and the top lid 174 may be made of a same material for manufacturing simplicity. In some embodiments, the contour ring 172 may be made of a material that is more rigid than a material of the top lid 174. Alternatively, the top lid 174 may be made of a material that is more rigid than a material of the contour ring 172. In some embodiments, the top lid 174 may be made of a material that has a higher thermal conductivity than a material of the contour ring 172, such that the top lid 174 may create a larger heat dissipation path for the dies 112, which in turn will improve the heat dissipation capability of the package structure.

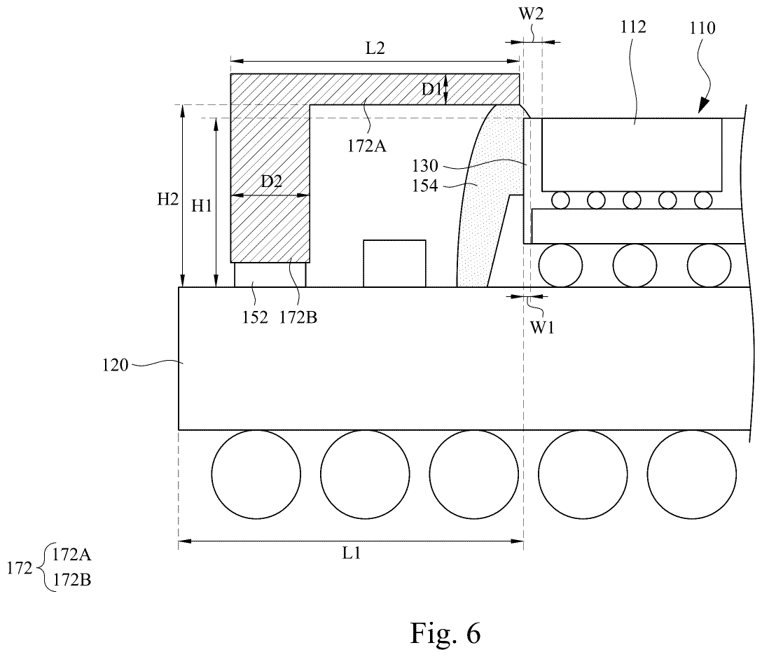

FIG. 6 is a cross-sectional view of a package structure in accordance with some embodiments of the present disclosure. In particular, FIG. 6 is an enlarged view of FIG. 3B. It is noted that some elements of FIG. 6 have been described above with respect to FIGS. 1A to 5B, such elements are labeled the same and relevant details will not be repeated for brevity.

The vertical distance between the top surface of substrate 120 and the top surface of the package 110 (or the top surface of die 112) is referred to as height H1. The vertical distance between the top surface of substrate 120 and the bottom surface of the horizontal portion 172A of the contour ring 172 is referred to as height H2. The horizontal portion 172A of the contour ring 172 has a vertical thickness D1, and the vertical portion 172B of the contour ring 172 has a lateral thickness D2. The interface length between the adhesive material 154 and the top surface of the package 110 (or the top surface of the encapsulant 130) is referred to as width W1. The distance between the outer sidewall of the encapsulant 130 and the nearest die 112 is referred to as width W2. The distance between the outer sidewall of the substrate 120 and the sidewall of the package 110 (or the sidewall of the encapsulant 130) is referred to as length L1. The distance between the outer sidewall of the contour ring 172 and the inner sidewall of the contour ring 172 is referred to as length L2 (ring length).

In some embodiments, the height H2 may be greater than the height H1. The thickness D1 may be equal to or greater than the height H1. For example, thickness D1 may be 1˜1.5×H1. The length L2 is less than the length L1. The thickness D2 is less than the length L1. For example, the thickness D2 is 0.3˜0.6×L1. These ensure a sufficient space for the contour ring 172 to be mounted on the substrate 120. The width W1 is less than the width W2. This ensures that the adhesive material 154 may not cover the top surface of the die 112, and will improve the package quality.

Embodiments of the present disclosure provide a package structure by mounting a contour ring 172 over the substrate 120, and then mounting a top lid 174 over the contour ring 172, in which the contour ring 172 has an opening that exposes the package 110 disposed on the substrate 120, and the top lid 174 has a portion (e.g., the lower portion 174B) extending into the opening of the contour ring 172. The robustness of contour ring 172 and the downward force during mounting the contour ring 172 may mitigate package warpage of the substrate 120, which in turn will reduce coplanarity (COP) issue after the contour ring 172 is attached on the substrate 120. For example, when warpage happens on the substrate 120 (e.g., the substrate 120 is bended), the contour ring 172 having an opening is first mounted over the substrate 120 without touching the package 110. As a result, a downward force can be applied only on the edge portions of the substrate 120, and the substrate 120 is pressed through the contour ring 172 to reduce the warpage. It is noted that during applying the downward force, the contour ring 172 may be secured to the substrate 120 by adhesives at more than one location (e.g., through the adhesive materials 152 and 154), which adds robustness and structural support to the contour ring 172. Because the warpage of the substrate 120 has been reduced, the thermal interface material 184 may be uniformly spread over the portion extending into the opening of the contour ring 172, which in turn will improve the heat dissipation efficiency. The thermal interface material 184 may also be in contact with the contour ring 172 and the top lid 174 after the top lid 174 is attached, and will further improve the heat dissipation efficiency. However, if a contour ring is mounted over the substrate 120 and touching the package 110 (through an adhesive material), the package 110 may press against the contour ring 172 during the mounting process, and the downward force may not be able to recover the bended substrate 120. In such condition, warpage may remain, and the COP issue may not be reduced, which may lead to an unsatisfied heat dissipation performance.

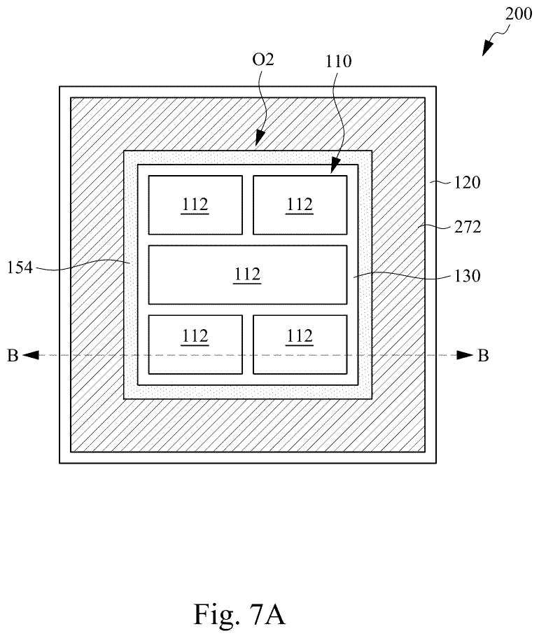

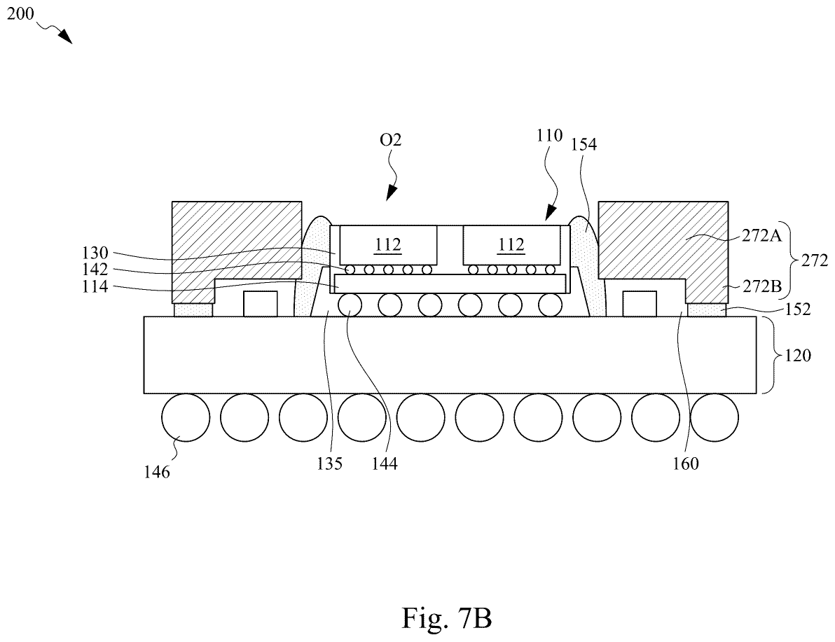

FIGS. 7A to 9B illustrate a method in various stages of forming a package structure in accordance with some embodiments of the present disclosure. FIGS. 7A, 8A, and 9A are top views of a package structure, and FIGS. 7B, 8B, and 9B are cross-sectional views of a package structure. In greater detail, FIGS. 7B, 8B, and 9B are cross-sectional views along line B-B of FIGS. 7A, 8A, and 9A, respectively. It is noted that some elements of FIGS. 7A to 9B have been described above with respect to FIGS. 1A to 5B, such elements are labeled the same and relevant details will not be repeated for brevity.

Reference is made to FIGS. 7A and 7B. A contour ring 272 is mounted over the substrate 120 and surrounding the package 110. The contour ring 272 of FIGS. 7A and 7B is different from the contour ring 172 discussed in FIGS. 1A to 5B in shape. In some embodiments, the contour ring 272 may also include an L-shape cross-sectional view. For example, the contour ring 272 may include a horizontal portion 272A and a vertical portion 272B extends downward from one end of the horizontal portion 272A. The vertical portion 272B is narrower than the horizontal portion 272A along the lateral direction. The horizontal portion 272A of the contour ring 272 is in contact with the adhesive material 154, and the vertical portion 272B of the contour ring 272 is in contact with the adhesive material 252. The adhesive material 154 may be in contact with the sidewall and the bottom surface of the horizontal portion 272A of the contour ring 272. In some embodiments, the bottom surface of the horizontal portion 272A of the contour ring 272 is lower than the top surfaces of the dies 112 and the encapsulant 130, while the top surface of the horizontal portion 272A of the contour ring 272 is higher than the top surfaces of the dies 112 and the encapsulant 130.

The contour ring 272 includes an opening O2. In some embodiments, the opening O2 may expose all of the dies 112 of the package 110. That is, in the cross-sectional view of FIG. 7B, the contour ring 272 may not overlap with the dies 112 along the vertical direction. In some embodiments, the contour ring 172 may not overlap with the encapsulant 130 that surrounds the dies 112.

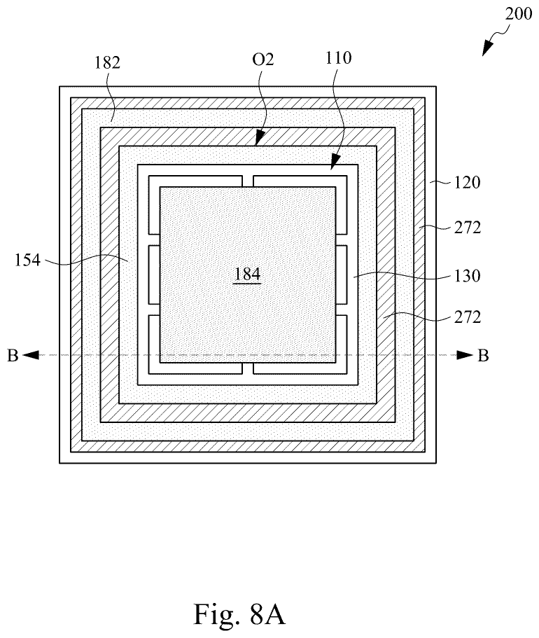

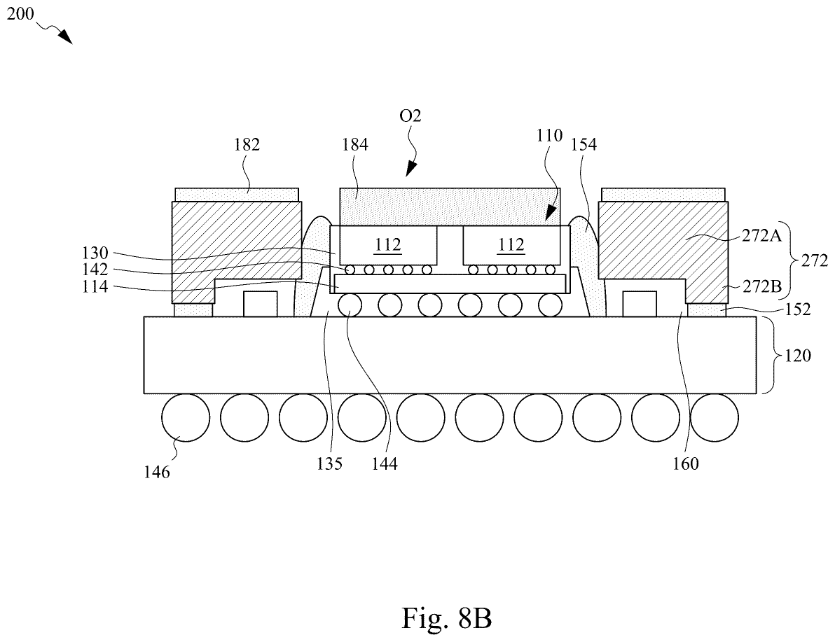

Reference is made to FIGS. 8A and 8B. An adhesive material 182 and a thermal interface material (TIM) 184 are dispensed over the contour ring 272 and the package 110, respectively. In greater detail, the adhesive material 182 is dispensed over and in contact with the horizontal portion 272A of the contour ring 272. The thermal interface material 184 is dispensed over and in contact with top surfaces of the dies 112 and the encapsulant 130. In some embodiments, the bottom surface of the thermal interface material 184 may be lower than the bottom surface of the adhesive material 182. The thermal interface material 184 may be spaced apart from the contour ring 172 and the adhesive material 182.

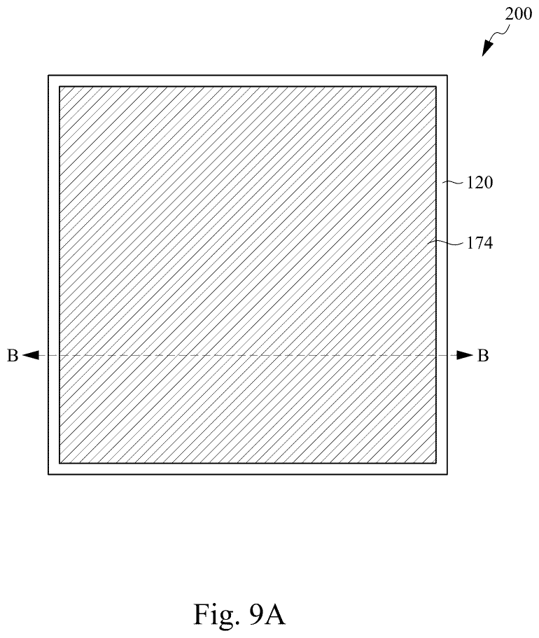

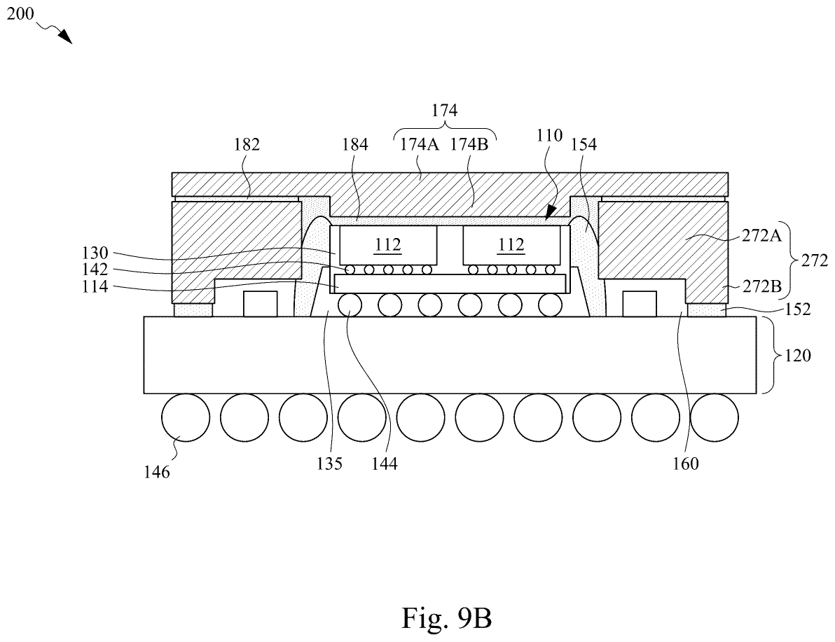

Reference is made to FIGS. 9A and 9B. A top lid 174 is mounted over the contour ring 272 and the package 110. The lower portion 174B of the top lid 174 extends into the opening O2 of the contour ring 272, such that the lower portion 174B of the top lid 174 may be laterally aligned, at least in part, with the horizontal portion 272A of the contour ring 272. The upper portion 174A of the top lid 174 may cover the package 110 and the contour ring 272. That is, the upper portion 174A of the top lid 174 may overlap with the contour ring 272 along the vertical direction. In greater detail, the upper portion 174A of the top lid 174 may overlap with the vertical portion 272B of the contour ring 272.

As a result, after the top lid 174 is mounted over the contour ring 272 and the package 110, the thermal interface material 184 may be in contact with sidewalls of the horizontal portion 272A of the contour ring 272. In some embodiments, the thermal interface material 184 may also extend to the top surface of the horizontal portion 272A of the contour ring 272 and in contact with the adhesive material 182. On the other hand, the thermal interface material 184 may be in contact with the bottom surface and sidewalls of the lower portion 174B of the top lid 174 and the bottom surface of the upper portion 174A of the top lid 174. In some embodiments, the thermal interface material 184 may extend to a position that is lower than the top surfaces of the dies 112 and the encapsulant 130.

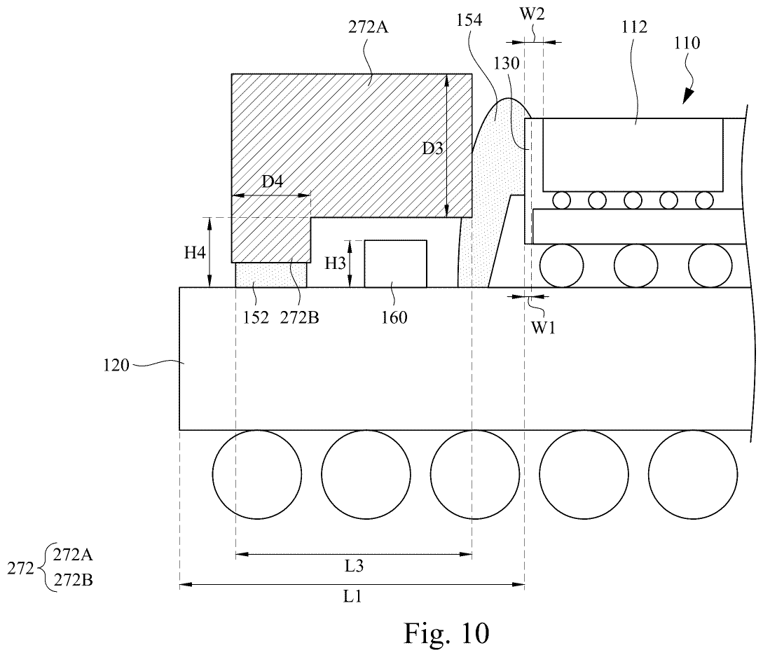

FIG. 10 is a cross-sectional view of a package structure in accordance with some embodiments of the present disclosure. In particular, FIG. 10 is an enlarged view of FIG. 7B. It is noted that some elements of FIG. 10 have been described above with respect to FIGS. 7A to 9B, such elements are labeled the same and relevant details will not be repeated for brevity.

The vertical distance between the top surface of substrate 120 and the top surface of the surface device 160 is referred to as height H3. The vertical distance between the top surface of substrate 120 and the bottom surface of the horizontal portion 272A of the contour ring 272 is referred to as height H4. The horizontal portion 272A of the contour ring 272 has a vertical thickness D3, and the vertical portion 272B of the contour ring 272 has a lateral thickness D4. The interface length between the adhesive material 154 and the top surface of the package 110 (or the top surface of the encapsulant 130) is referred to as width W1. The distance between the outer sidewall of the encapsulant 130 and the nearest die 112 is referred to as width W2. The distance between the outer sidewall of the substrate 120 and the sidewall of the package 110 (or the sidewall of the encapsulant 130) is referred to as length L1. The distance between the outer sidewall of the contour ring 172 and the inner sidewall of the contour ring 172 is referred to as length L3 (ring length).

The height H4 may be greater than the height H3. The thickness D3 may be equal to or greater than the height H3. For example, thickness D3 may be 2˜2.5×H3. The length L3 is less than the length L1. The thickness D4 is less than the length L1. For example, the thickness D4 is 0.3˜0.6×L1. This ensures a sufficient space for the contour ring 172 to be mounted on the substrate 120. The width W1 is less than the width W2. This ensures that the adhesive material 154 may not cover the top surface of the die 112, and will improve the package quality.

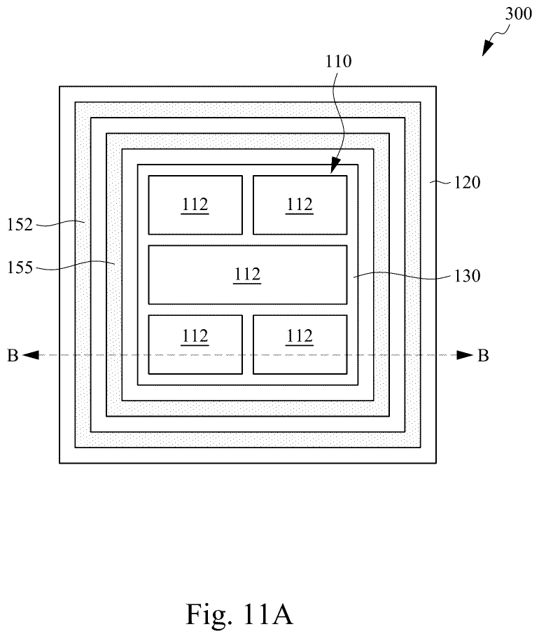

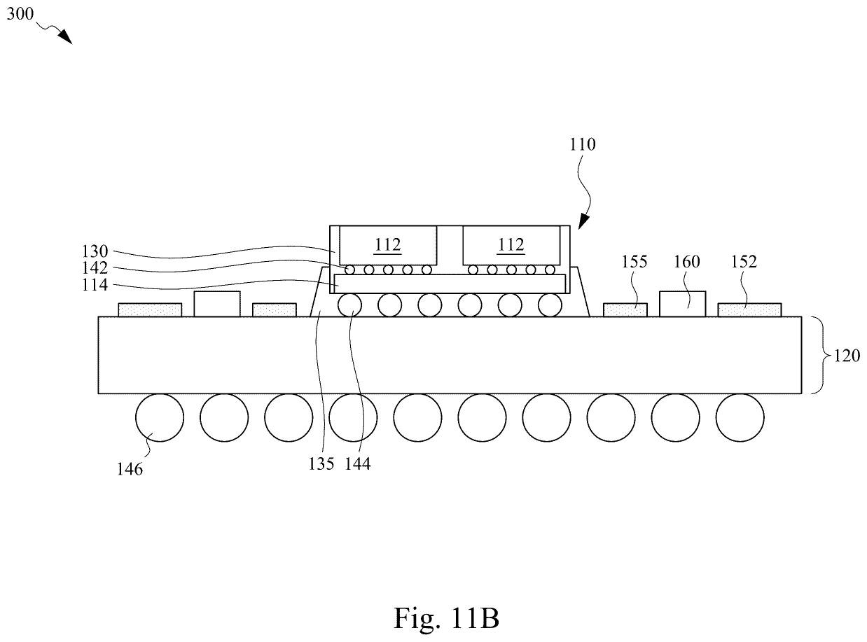

FIGS. 11A to 14B illustrate a method in various stages of forming a package structure in accordance with some embodiments of the present disclosure. FIGS. 11A, 12A, 13A, and 14A are top views of a package structure, and FIGS. 11B, 12B, 13B, and 14B are cross-sectional views of a package structure. In greater detail, FIGS. 11B, 12B, 13B, and 14B are cross-sectional views along line B-B of FIGS. 11A, 12A, 13A, and 14A, respectively. It is noted that some elements of FIGS. 11A to 14B have been described above with respect to FIGS. 1A to 5B, such elements are labeled the same and relevant details will not be repeated for brevity.

Reference is made to FIGS. 11A and 11B. Adhesive materials 152 and 155 are dispensed over the substrate 120. In the top view of FIG. 11A, both of the adhesive materials 152 and 155 have a rectangular ring shape top profile. In greater detail, the adhesive material 152 surrounds the adhesive material 155. Moreover, the adhesive material 155 may surround the dies 112, and may also surround the encapsulant 130. In the cross-sectional view of FIG. 11B, the adhesive material 155 is spaced apart from the package 110. Each of the surface devices 160 is between the adhesive material 152 and the adhesive material 155.

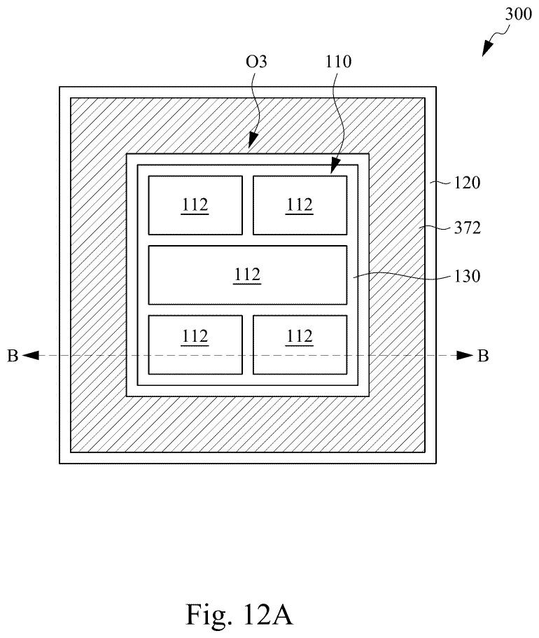

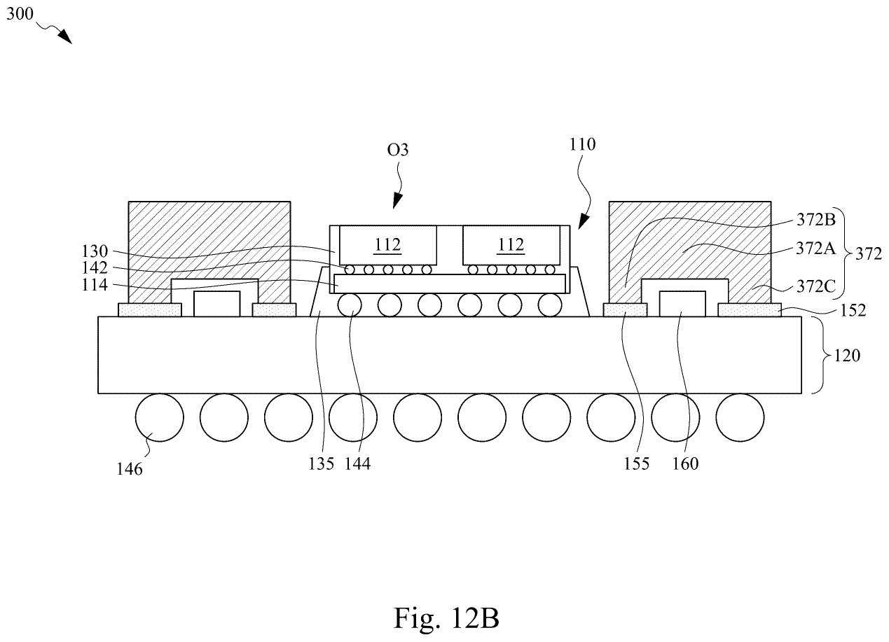

Reference is made to FIGS. 12A and 12B. A contour ring 372 is mounted over the substrate 120 and surrounding the package 110. As shown in the top view of FIG. 12A, the contour ring 372 has a rectangular ring shape top profile, which includes an opening O3. On the other hand, as shown in the cross-sectional view of FIG. 12B, the contour ring 372 is connected to the substrate 120 through the adhesive materials 152 and 155. The contour ring 372 may include a horizontal portion 372A and vertical portions 372B and 372C extends downward from opposite ends of the horizontal portion 372A. The vertical portions 372B and 372C are in contact with the adhesive materials 152 and 155, respectively. In some embodiments, the bottom surface of the horizontal portion 372A of the contour ring 372 is lower than the top surfaces of the dies 112 and the encapsulant 130, while the top surface of the horizontal portion 372A of the contour ring 372 is higher than the top surfaces of the dies 112 and the encapsulant 130.

As mentioned above, the contour ring 372 includes an opening O3. In some embodiments, the opening O3 may expose all of the dies 112 of the package 110. That is, in the cross-sectional view of FIG. 3B, the contour ring 372 may not overlap with the dies 112 along the vertical direction. In some embodiments, the contour ring 372 may not overlap with the encapsulant 130 and the underfill material 135.

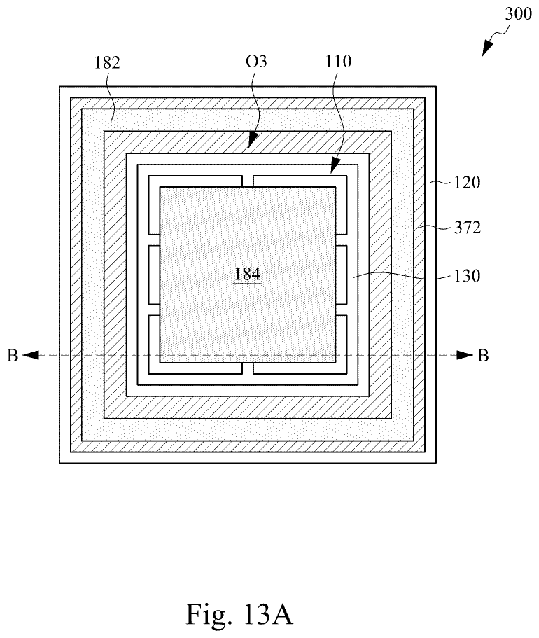

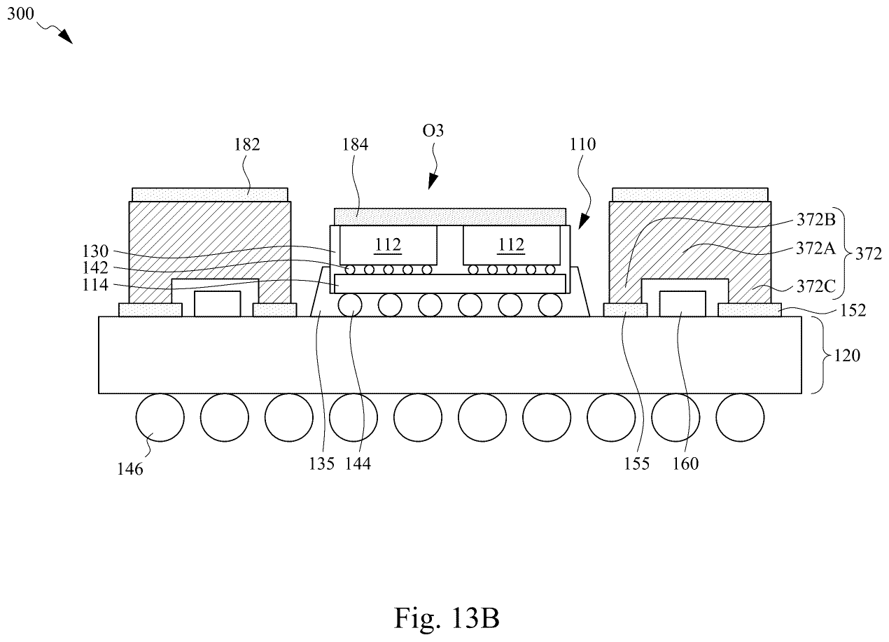

Reference is made to FIGS. 13A and 13B. An adhesive material 182 and a thermal interface material (TIM) 184 are dispensed over the contour ring 372 and the package 110, respectively. In greater detail, the adhesive material 182 is dispensed over and in contact with the horizontal portion 372A of the contour ring 372. The thermal interface material 184 is dispensed over and in contact with top surfaces of the dies 112 and the encapsulant 130. In some embodiments, the bottom surface of the thermal interface material 184 may be lower than the bottom surface of the adhesive material 182. The thermal interface material 184 may be spaced apart from the contour ring 372 and the adhesive material 182.

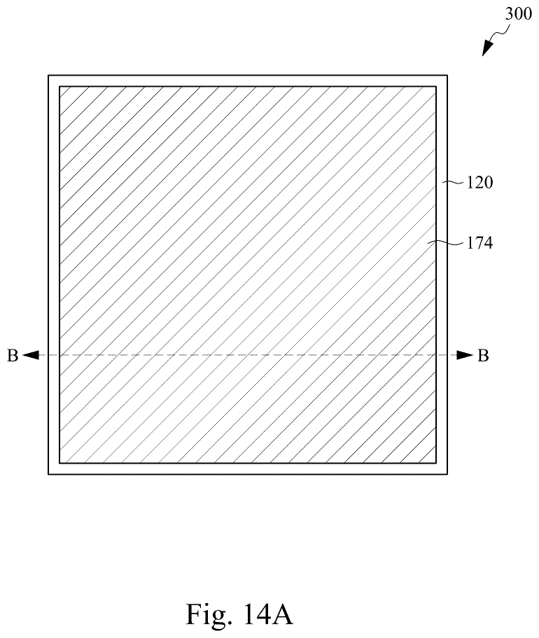

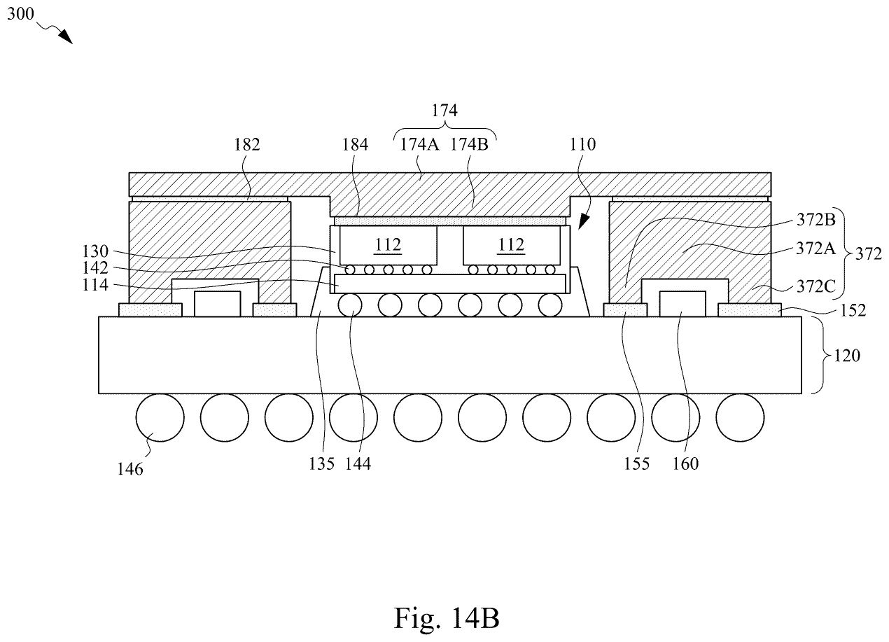

Reference is made to FIGS. 14A and 14B. A top lid 174 is mounted over the contour ring 272 and the package 110. The lower portion 174B of the top lid 174 extends into the opening O3 of the contour ring 372, such that the lower portion 174B of the top lid 174 may be laterally aligned, at least in part, with the horizontal portion 372A of the contour ring 372. The upper portion 174A of the top lid 174 may cover the package 110 and the contour ring 372. That is, the upper portion 174A of the top lid 174 may overlap with the contour ring 372 along the vertical direction.

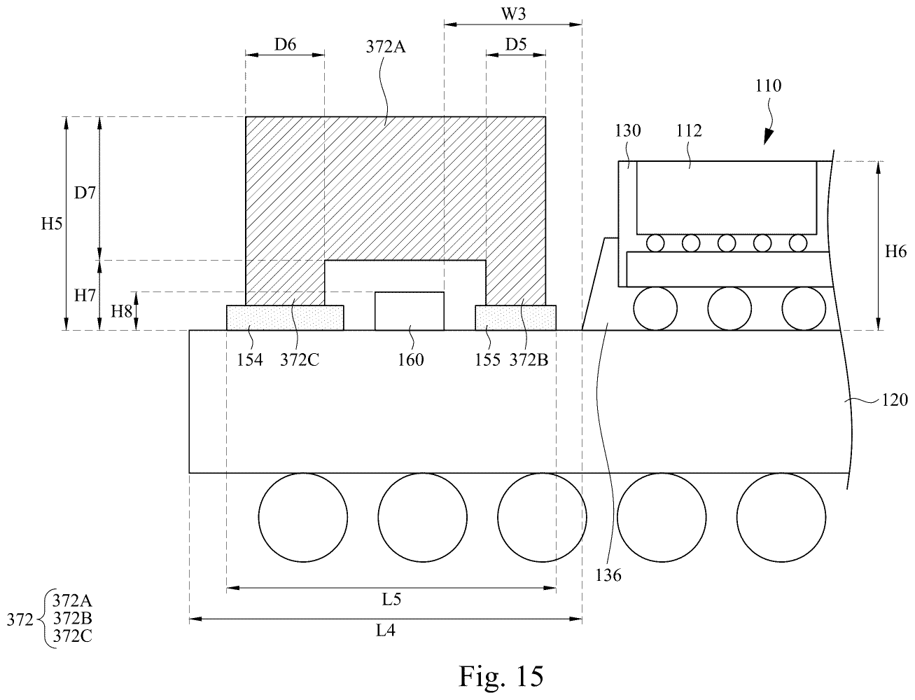

FIG. 15 is a cross-sectional view of a package structure in accordance with some embodiments of the present disclosure. In particular, FIG. 15 is an enlarged view of FIG. 12B. It is noted that some elements of FIG. 15 have been described above with respect to FIGS. 11A to 14B, such elements are labeled the same and relevant details will not be repeated for brevity.

The vertical distance between the top surface of substrate 120 and the top surface of the surface device 160 is referred to as height H8. The vertical distance between the top surface of substrate 120 and the top surface of the horizontal portion 372A of the contour ring 372 is referred to as height H5. The vertical distance between the top surface of substrate 120 and the top surface of the package 110 is referred to as height H6. The vertical distance between the top surface of substrate 120 and the bottom surface of the horizontal portion 372A of the contour ring 372 is referred to as height H7. The vertical portion 372B of the contour ring 372 has a lateral thickness D5, and the vertical portion 372C of the contour ring 372 has a lateral thickness D6. The horizontal portion 372A has a vertical thickness D7. The distance between the surface device 160 and the underfill material 135 is referred to as width W3. The distance between the outer sidewall of the encapsulant 130 and the nearest die 112 is referred to as W2. The distance between the outer sidewall of the substrate 120 and the underfill material 135 is referred to as length L4. The distance between the outer sidewall of the contour ring 372 and the inner sidewall of the contour ring 372 is referred to as length L5 (ring length).

The height H7 may be greater than the height H8. The height H5 may be greater than the height H6. For example, height H5 may be 3-3.5×H6. The length L5 is less than the length L4. The thickness D5 is less than the width W3. This ensures that the vertical portion 372B can be placed between the surface device 160 and the underfill material 135. The sum of the thicknesses D5 and D6 may be less than the distance L4. For example, the sum of the thicknesses D5 and D6 (e.g., D5+D6) may be 0.5-0.8×L4. In some embodiments the thickness D6 is different from the thickness D5 for better COP reduction. For example, the thickness D6 may be greater than the thickness D5 for preventing COP issue. In other embodiments, the thickness D6 is substantially the same as the thickness D5 for manufacturing simplicity. In some embodiments, the thickness D7 is greater than the thicknesses D5 and D6. That is, the horizontal portion 372A is thicker than the vertical portions 372B and 372C.

The extra portion (e.g., the vertical portion 372B) of the contour ring 372 between the surface device 160 and the underfill material 135 can provide better ring adhesion to the substrate 120. The better ring adhesion, the robustness of contour ring 372, and the downward force during mounting the contour ring 372 may mitigate package warpage of the substrate 120, which in turn will reduce coplanarity (COP) issue after the contour ring 372 is attached on the substrate 120. Because the warpage of the substrate 120 has been reduced, the thermal interface material 184 may be uniformly spread over the portion extending into the opening of the contour ring 172, which in turn will improve the heat dissipation efficiency.

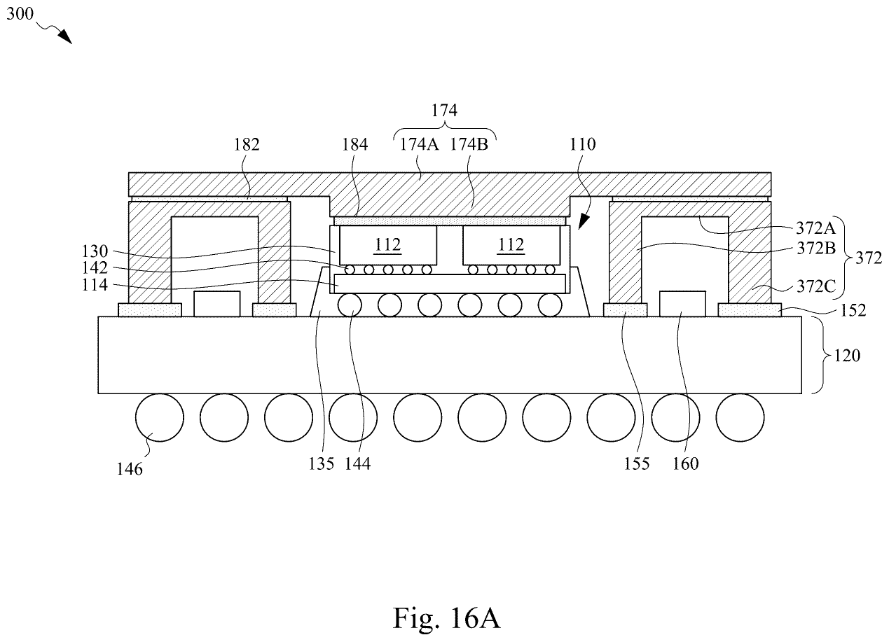

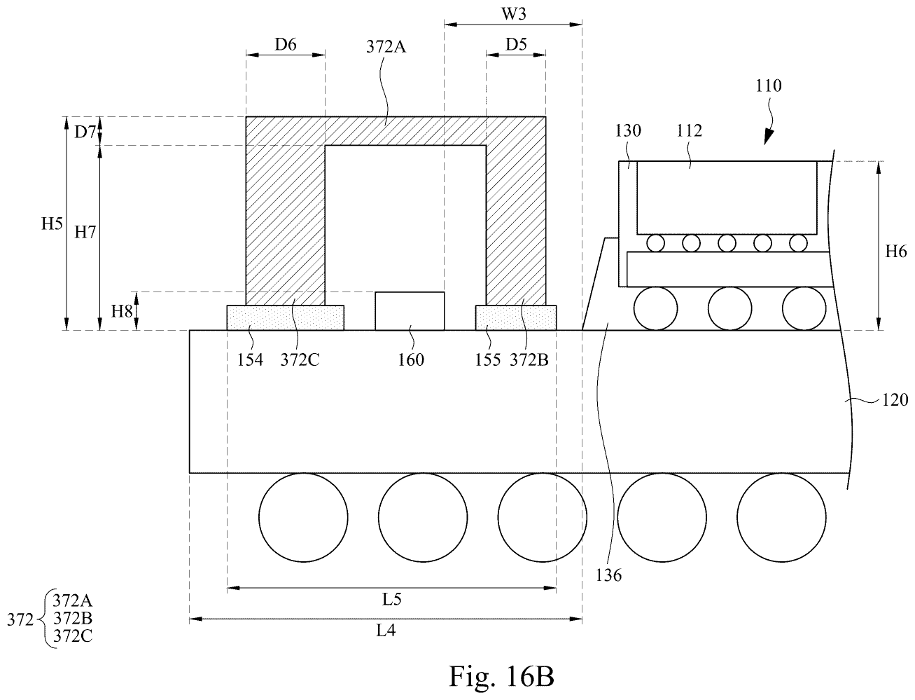

FIGS. 16A and 16B are cross-sectional views of a package structure in accordance with some embodiments of the present disclosure. In greater detail, FIG. 16B is an enlarged view of FIG. 16A. FIG. 16A is similar to FIG. 14B, and FIG. 16B is similar to FIG. 15, the difference is that in the structure of FIGS. 16A and 16B, the thickness D7 of the horizontal portion 372A of the contour ring 372 is smaller than the thicknesses D5 and D6 of the vertical portions 372B and 372C. That is, the horizontal portion 372A is thinner than the vertical portions 372B and 372C. Moreover, the height H7 may be greater than the height H6. That is, the bottom surface of the horizontal portion 372A of the contour ring 372 may be higher than the top surface of the package 110. Such configuration allows more spaces for surface devices 160 having different thicknesses, and may be beneficial for manufacturing flexibility.

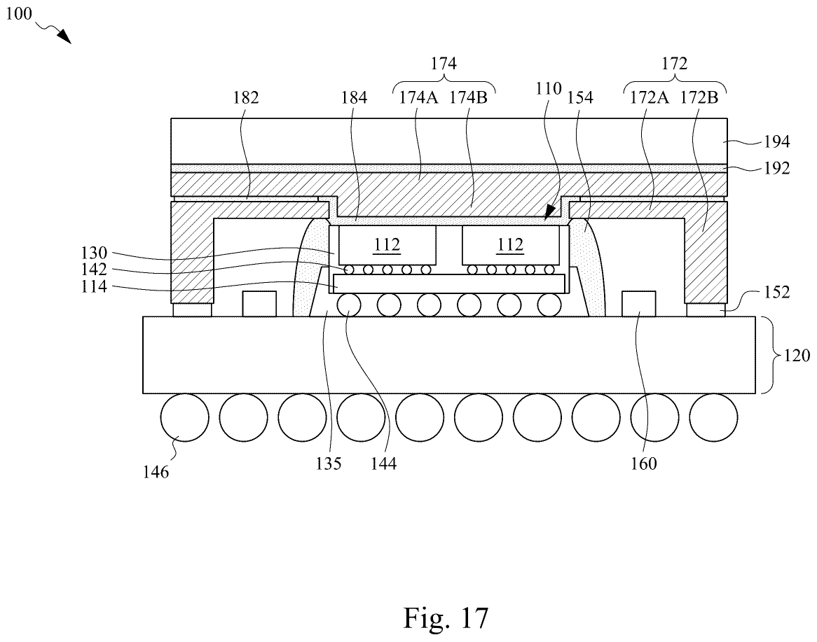

FIG. 17 is a cross-sectional view of a package structure in accordance with some embodiments of the present disclosure. FIG. 17 is similar to FIG. 5B, in which a heat spreader 194 is additionally mounted over the top lid 174 through a thermal interface material 192. The thermal interface material 192 may include a similar material as the thermal interface material 184. In some embodiments, the heat spreader 194 may include a heat sink and/or a cooling device. For example, a heat sink may include a planar bottom surface, to which the thermal interface material 192 is attached. The heat sink may also include a plurality of fins, with a plurality of trenches separating the plurality of fins. The cooling device may be a fanning device, such as a fan. It is noted that the heat spreader 194 may also be applied to the structures of FIGS. 9B, 14B, and 16A. That is, a heat spreader 194 may be mounted over the top lid 174 of the structures of FIGS. 9B, 14B, and 16A through a thermal interface material 192.

According to the aforementioned embodiments, it can be seen that the present disclosure offers advantages in fabricating integrated circuits. It is understood, however, that other embodiments may offer additional advantages, and not all advantages are necessarily disclosed herein, and that no particular advantage is required for all embodiments. Embodiments of the present disclosure provide a package structure by mounting a contour ring over a substrate, and then mounting a top lid over the contour ring, in which the contour ring has an opening that exposes a package disposed on the substrate, and the top lid has a portion extending into the opening of the contour ring. The robustness of contour ring and the downward force during mounting the contour ring may mitigate package warpage of the substrate, which in turn will reduce coplanarity (COP) issue after the contour ring is attached on the substrate. For example, when warpage happens on the substrate (e.g., the substrate is bended), the contour ring having an opening is first mounted over the substrate without touching the package over the substrate. As a result, a downward force can be applied only on the edge portions of the substrate, and the substrate is pressed through the contour ring to reduce the warpage. It is noted that during applying the downward force, the contour ring may be secured to the substrate by adhesives at more than one location, which adds robustness and structural support to the contour ring. Because the warpage of the substrate has been reduced, the thermal interface material may be uniformly spread over the portion extending into the opening of the contour ring, which in turn will improve the heat dissipation efficiency. The thermal interface material may also be in contact with the contour ring and the top lid after the top lid is attached, and will further improve the heat dissipation efficiency.

In some embodiments of the present disclosure, a package structure includes a substrate. A package is over the substrate. A contour ring is mounted over the substrate, in which the contour ring surrounds the package and has an opening. A top lid is mounted over the contour ring, in which the top lid has a portion extending into the opening of the contour ring.

In some embodiments, the package structure further includes an adhesive material along a surface of the package, wherein the contour ring is mounted over the substrate through the adhesive material.

In some embodiments, the package structure further includes a thermal interface material between the package and the portion of the top lid.

In some embodiments, the thermal interface material is in contact with the contour ring.

In some embodiments, in a cross-sectional view, the contour ring includes a horizontal portion and a first vertical portion extending downward from one end of the horizontal portion, and the first vertical portion is narrower than the horizontal portion along a lateral direction.

In some embodiments, in the cross-sectional view, the contour ring further includes a second vertical portion extending downward from another end of the horizontal portion, and the second vertical portion is narrower than the horizontal portion along the lateral direction.

In some embodiments, the package structure further includes a surface device mounted over the substrate and laterally between the first vertical portion and the second vertical portion of the contour ring.

In some embodiments, the second vertical portion is closer to the package than the first vertical portion, and the second vertical portion is narrower than the first vertical portion along the lateral direction.

In some embodiments of the present disclosure, a package structure includes a substrate. A package is over the substrate and comprising a plurality of dies. A contour ring is over the substrate, wherein the contour ring includes a horizontal portion and a vertical portion extending downward from one end of the horizontal portion. A top lid is mounted over the contour ring, wherein in a top view, the top lid includes a first portion overlapping with the horizontal portion of the contour ring and a second portion overlapping with the dies of the package.

In some embodiments, a bottommost surface of the top lid is lower than a top surface of the horizontal portion of the contour ring

In some embodiments, the package structure further includes an adhesive material extending from a top surface of the package to a top surface of the substrate, wherein the adhesive material is in contact with the horizontal portion of the contour ring.

In some embodiments, the dies of the package are free of coverage by the contour ring.

In some embodiments, a bottom surface of the horizontal portion of the contour ring is higher than a top surface of the package.

In some embodiments, a bottom surface of the horizontal portion of the contour ring is lower than a top surface of the package.

In some embodiments, the top lid comprises an upper portion and a lower portion under the upper portion, the upper portion of the top lid is wider than the lower portion of the top lid, and the upper portion of the top lid vertically overlaps with the vertical portion of the contour ring.

In some embodiments of the present disclosure, a method includes mounting a package comprises a plurality of dies over a substrate; dispensing a first adhesive material and a second adhesive material over the substrate and surrounding the package, wherein the first adhesive material surrounds the second adhesive material; mounting a contour ring over the substrate and in contact with the first adhesive material and the second adhesive material; and mounting a top lid over the contour ring.

In some embodiments, the top lid has an upper portion and a lower portion extending downward from the upper portion, and the lower portion of the top lid extends into an opening of the contour ring, and the upper portion of the top lid is above a top surface of the contour ring.

In some embodiments, the contour ring includes a horizontal portion and one or more vertical portions extending downward from the horizontal portion.

In some embodiments, the method further includes, prior to mounting the top lid over the contour ring, dispensing a third adhesive material over the contour ring and a thermal interface material over the package, wherein the top lid is in contact with the thermal interface material and the third adhesive material.

In some embodiments, the thermal interface material is spaced apart from the third adhesive material and the contour ring prior to mounting the top lid over the contour ring, and the thermal interface material is in contact with the third adhesive material and the contour ring after mounting the top lid over the contour ring.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a substrate;
a package over the substrate;
a contour ring mounted over the substrate, wherein the contour ring surrounds the package and has an opening; and
a top lid mounted over the contour ring, wherein the top lid has a portion extending into the opening of the contour ring.

2. The package structure of claim 1, further comprising an adhesive material along a surface of the package, wherein the contour ring is mounted over the substrate through the adhesive material.

3. The package structure of claim 1, further comprising a thermal interface material between the package and the portion of the top lid.

4. The package structure of claim 3, wherein the thermal interface material is in contact with the contour ring.

5. The package structure of claim 1, wherein in a cross-sectional view, the contour ring includes a horizontal portion and a first vertical portion extending downward from one end of the horizontal portion, and the first vertical portion is narrower than the horizontal portion along a lateral direction.

6. The package structure of claim 5, wherein in the cross-sectional view, the contour ring further includes a second vertical portion extending downward from another end of the horizontal portion, and the second vertical portion is narrower than the horizontal portion along the lateral direction.

7. The package structure of claim 6, further comprising a surface device mounted over the substrate and laterally between the first vertical portion and the second vertical portion of the contour ring.

8. The package structure of claim 6, wherein the second vertical portion is closer to the package than the first vertical portion, and the second vertical portion is narrower than the first vertical portion along the lateral direction.

9. A package structure, comprising:
a substrate;
a package over the substrate and comprising a plurality of dies;
a contour ring over the substrate, wherein the contour ring includes a horizontal portion and a vertical portion extending downward from one end of the horizontal portion; and
a top lid mounted over the contour ring, wherein in a top view, the top lid includes a first portion overlapping with the horizontal portion of the contour ring and a second portion overlapping with the dies of the package.

10. The package structure of claim 9, wherein a bottommost surface of the top lid is lower than a top surface of the horizontal portion of the contour ring.

11. The package structure of claim 9, further comprising an adhesive material extending from a top surface of the package to a top surface of the substrate, wherein the adhesive material is in contact with the horizontal portion of the contour ring.

12. The package structure of claim 9, wherein the dies of the package are free of coverage by the contour ring.

13. The package structure of claim 9, wherein a bottom surface of the horizontal portion of the contour ring is higher than a top surface of the package.

14. The package structure of claim 9, wherein a bottom surface of the horizontal portion of the contour ring is lower than a top surface of the package.

15. The package structure of claim 9, wherein the top lid comprises an upper portion and a lower portion under the upper portion, the upper portion of the top lid is wider than the lower portion of the top lid, and the upper portion of the top lid vertically overlaps with the vertical portion of the contour ring.

16. A method, comprising:
mounting a package comprises a plurality of dies over a substrate;
dispensing a first adhesive material and a second adhesive material over the substrate and surrounding the package, wherein the first adhesive material surrounds the second adhesive material;
mounting a contour ring over the substrate and in contact with the first adhesive material and the second adhesive material; and
mounting a top lid over the contour ring.

17. The method of claim 16, wherein the top lid has an upper portion and a lower portion extending downward from the upper portion, and the lower portion of the top lid extends into an opening of the contour ring, and the upper portion of the top lid is above a top surface of the contour ring.

18. The method of claim 17, wherein the contour ring includes a horizontal portion and one or more vertical portions extending downward from the horizontal portion.

19. The method of claim 17, further comprising, prior to mounting the top lid over the contour ring, dispensing a third adhesive material over the contour ring and a thermal interface material over the package, wherein the top lid is in contact with the thermal interface material and the third adhesive material.

20. The method of claim 19, wherein the thermal interface material is spaced apart from the third adhesive material and the contour ring prior to mounting the top lid over the contour ring, and the thermal interface material is in contact with the third adhesive material and the contour ring after mounting the top lid over the contour ring.
